(19) United States
(12) Patent Application Publication
(10) Pub. No.: US 2009/0250101 A1
(43) Pub. Date: Oct. 8, 2009

(54) Photovoltaic structure

(76) Inventors: Yi-An Chang, Hsinchu Hsien (TW); Jui-Yen Tsai, Hsinchu Hsien (TW); Li-Wen Lai, Hsinchu Hsien (TW); Li-Hung Lai, Hsinchu Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/078,691

(22) Filed: Apr. 4, 2008

(51) Int. Cl. H01L 31/0336; H01L 31/04

(52) U.S. Cl. 136/255; 136/262; 257/E31.005

(57) ABSTRACT

A photovoltaic structure is provided with an added layer inserted between an emitter layer and a window layer. The added layer includes all elements which are same or different both in the emitter layer and the window layer. The addition of the added layer enhances converted current and voltage that improves the conversion efficiency when the structure is applied to a solar cell.

### BACKGROUND OF THE INVENTION

1. Field of the Invention

The present invention relates to a photovoltaic structure, and more especially, to a thin-film photovoltaic structure.

2. Background of the Related Art

Solar cell, also called photovoltaic cell, is a device for converting sun light into electrical power and has many advantages, such as no noise, no waste, no pollution, high reliability, high duration, and low maintenance cost, suitable for various applications. Most of the solar cells for sale are based on silicon material to have high reliability but in company with the drawback of a high series resistance. Nowadays, some resolutions include reducing the cost of silicon material or assembly, enhancing the efficiency of solar cell or concentration system, or developing a manufacturing technology for new material or the device.

The materials of thin film solar cell may be single element, binary elements and ternary elements as follows: (1) polycrystalline silicon or amorphous silicon-hydrogen alloy (Si—H) belonging to single element; (2) GaAs or InP solar cell of group III-V compound semiconductor material belonging to binary elements; (3) CuS/CdS solar cell of group II-VI compound semiconductor material; and (4) CuInSe₂/CdS and CuInS solar cell belonging to ternary elements.

FIG. 1 is a schematically cross-sectional diagram illustrating traditional thin-film solar cell made by group III-V compound semiconductor material. A back surface field layer 112 (BSF), a base layer 114, an emitter layer 116, a window layer 118, and an ohmic contact layer 120 are sequentially formed on a substrate 110.

Gallium arsenide based solar cell has features as follows: (1) good energy band gap (1.42 eV) as well as high efficiency and thermal stability; (2) the material of direct energy band gap as well as strong light absorption suitable for a thin-film solar cell (in thickness of about 2-3 micrometers enough to absorb whole sun light); and (3) light suitable for a space power battery. However, such a battery also has some drawbacks, such as: (1) high cost; and (2) unknown factors in a manufacturing process to affect the battery performance so as to make no effort on efficiency enhancement. Some improvement methods include optimizing each thin film in a battery, integration of thickness and doping concentration in each thin film, or process enhancement. However, it is still limited to improve efficiencies by those methods aforementioned.

### SUMMARY OF THE INVENTION

The present invention is to provide a thin-film photovoltaic structure which includes an added layer sandwiched between an emitting layer and a window layer for photovoltaic enhancement.

Further, the present invention is to provide a thin-film semiconductor photovoltaic structure which has a quaternary semiconductor alloy composition formed on an emitting layer of a ternary semiconductor alloy composition for power support of a photovoltaic cell.

Accordingly, one of embodiments of the present invention provides a photovoltaic structure which includes a substrate, a back surface field layer on the substrate, a base layer on the back surface field layer, an emitter layer on the base layer, a window layer on the emitter layer, an added layer between the emitter layer and the window layer, and an ohmic contact layer on the window layer. The emitter layer is an alloy composition including a common component and a first component. The window layer is an alloy composition including the common component and a second component. An added layer is between the emitter layer and the window layer. The added layer is an alloy composition including the common component, the first and the second components.

These and other aspects, features and advantages of the present invention can be further understood from the accompanying drawings and description of a preferred embodiment.

### BRIEF DESCRIPTION OF THE DRAWINGS

FIG. 1 is a schematically cross-sectional diagram illustrating a conventional film cell made by group III-V compound semiconductor material.

FIG. 2 is a schematically cross-sectional diagram illustrating a photovoltaic structure in accordance with one embodiment of the present invention.

### DETAILED DESCRIPTION OF THE INVENTION

FIG. 2 is a schematically cross-sectional diagram illustrating a photovoltaic structure in accordance with one embodiment of the present invention. It is noted that a group III-V compound semiconductor alloy composition is exemplarily illustrated, such as one mainly based on binary, ternary, or quaternary semiconductor alloy composition. It is understood that a small amount of other component may be added in the semiconductor alloy composition for physical enhancement. However, such a semiconductor alloy composition herein is a binary, ternary, or quaternary.

Shown in FIG. 2, a substrate 10, which is not involved in a photovoltaic reaction, is provided herein. For example, the group III-V based compound substrate 10, such as GaAs or InP, may be with various characteristics by different forming method for enhancing the efficiency of a photovoltaic cell. In the embodiment, the substrate 10 is made of n-GaAs. A back surface field layer 12 (BSF layer), such as an n-InAlP ternary semiconductor alloy composition, is positioned on the substrate 10 and configured for blocking carriers (holes) from diffusing into the substrate 10. A base layer 14, an emitter layer 16 and a window layer 18 are sequentially formed on the back surface field layer 12. In the embodiment, the base layer 14 is an n-InGaP layer; the emitter layer 16 is a p-InGaP layer; and the window layer 18 is a p-InAlP layer. Moreover, an ohmic contact layer 20, such as a p-GaAs, is formed on the window layer 18.

Specially, in the present invention, an added layer 17 is sandwiched between the emitter layer 16 and the window layer 18. In addition to a common component, the emitter layer 16 and the window layer 18, which are ternary semiconductor alloy compositions, further include a first component and a second component different from each other. It is noted that the common component herein may include one or more same elements. However, the percentages of elements in the common component may be identical or different in the emitter layer 16 and the window layer 18, respectively.

Furthermore, the added layer 17 is a quaternary semiconductor alloy composition which includes the common, first and second components in both the emitter layer 16 and the window layer 18. The added layer 17 may be a p-InGaAlP layer or one layer represented as p-In_{0.5}(GaₓAl₁₋ₓ)_{0.5}P where x is between zero and 1. In the embodiment, in the added layer 17, the percentage of one component different from one in the emitter layer 16 is relatively little where is close to the interface of the emitter layer 16 and the added layer 17. That is, in the added layer 17, the second component is less than the first component where the added layer 17 is close to the emitter layer 16. The second component is gradually increased in the added layer 17 where the added layer 17 is gradually away from the emitter layer 16. Accordingly, the composition of the added layer 17 near the window layer 18 may be identical or similar to the window layer 18 by increasing the second component in the added layer 17. For example, for the added layer 17 represented as p-In_{0.5}(GaₓAl₁₋ₓ)_{0.5}P, gallium (Ga) is far more than aluminum (Al) where the added layer 17 is close to the emitter layer 16 of the first ternary semiconductor alloy composition p-InGaP. Where the position of the added layer 17 is away from the emitter layer 16, gallium (Ga) is gradually decreased while aluminum (Al) is gradually increased. The aluminum (Al) is far more than gallium (Ga) where the added layer 17 is closed to the window layer 18. That is, the composition of the added layer 17 is similar to the window layer 18 of the second ternary semiconductor alloy composition p-InAlP.

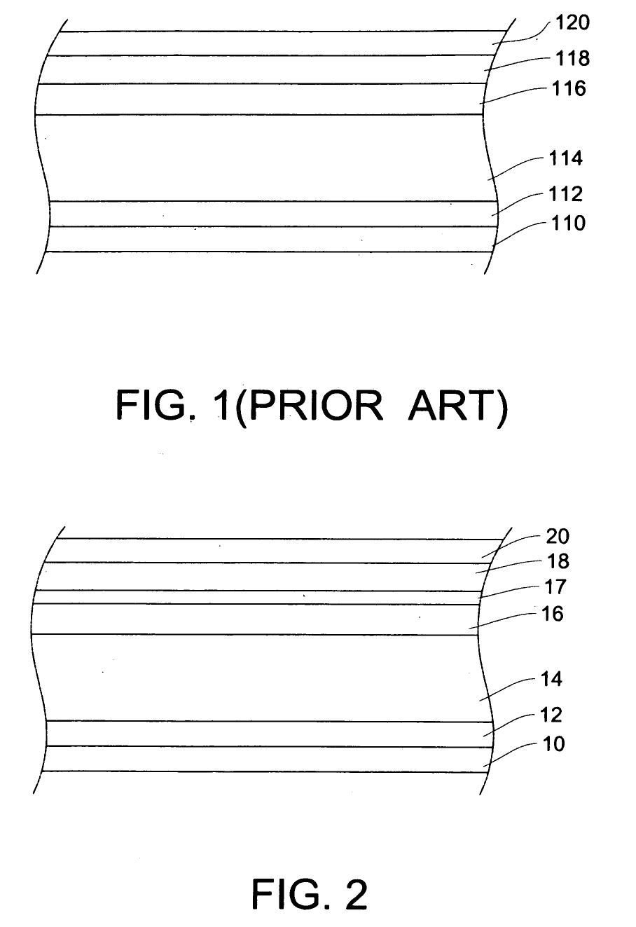

Next, the thickness of the added layer 17 is not limited, which may be adapted to other layers to have a thickness without influence on a whole thickness. However, the existence of the added layer 17 of the quaternary semiconductor alloy composition makes a device in an effort to convert current and enhance voltage. Compared with some photovoltaic parameters, such as short-circuit current J_{sc} (mA/cm²), open-circuit voltage V_{oc} (V), maximum power point Jₘ (mA/cm²), maximum voltage Vₘ (V), maximum power Pₘ (mW), fill factor FF, and conversion efficiency (%), a conventional structure (FIG. 1) is with J_{sc}=12.37 mA/cm², V_{oc}=1.37 V, Jₘ=11.26 mA/cm², Vₘ=1.26 V, FF=0.837, Pₘ=14.19 mW, and conversion efficiency=14.19%. On the condition of sandwiching the added layer 17 between the emitting layer 16 and the window layer 18, J_{sc} is between 12.63 and 12.71 mA/cm², V_{oc} between 1.40 and 1.41 V, Jₘ between 11.42 and 1.70 mA/cm², Vₘ between 1.26 and 1.29 V, FF between 0.826 and 0.830, Pₘ between 14.69 and 14.78 mW, and conversion efficiency between 14.69 and 14.78%. According to the parameters aforementioned, the added layer 17 is profitable to enhance the solar cell output characteristics.

Although the present invention has been explained in relation to its preferred embodiment, it is to be understood that other modifications and variation can be made without departing the spirit and scope of the invention as hereafter claimed.

What is claimed is:

1. A photovoltaic structure, comprising:
a substrate;
a back surface field layer on the substrate;
a base layer on the back surface field layer;
an emitter layer on the base layer, wherein the emitter layer is an alloy composition including a common component and a first component;
a window layer on the emitter layer, wherein the window layer is an alloy composition including the common component and a second component;
an added layer between the emitter layer and the window layer, wherein the added layer is an alloy composition including the common component, the first and the second components; and
an ohmic contact layer on the window layer.

2. The photovoltaic structure according to claim 1, wherein, in the added layer, the first component is more than the second component where the added layer is close to the emitter layer.

3. The photovoltaic structure according to claim 2, wherein, in the added layer, the first component is less than the second component where the added layer is close to the window layer.

4. The photovoltaic structure according to claim 2, wherein the common component comprises one or more semiconductor elements.

5. The photovoltaic structure according to claim 1, wherein the common component comprises indium and phosphorous.

6. The photovoltaic structure according to claim 5, wherein the first component is gallium.

7. The photovoltaic structure according to claim 6, wherein the second component is aluminum.

8. The photovoltaic structure according to claim 1, wherein the common component is a plurality of group III-V compound semiconductor elements.

9. A photovoltaic structure, comprising:
an n-type gallium arsenide based compound substrate;
an n-type indium aluminum phosphide based back surface field layer on the n-type gallium arsenide based compound substrate;
an n-type indium gallium phosphide based base layer on the back surface field layer;
a p-type indium gallium phosphide based emitter layer on the base layer;
a p-type indium aluminum phosphide based window layer on the emitter layer, wherein the window layer is an alloy composition including the common component and a second component;
a p-type indium aluminum gallium phosphide based added layer between the emitter layer and the window layer; and
a p-type gallium arsenide ohmic contact layer on the window layer.

10. The photovoltaic structure according to claim 9, wherein, in the added layer, gallium is more than aluminum where the added layer is close to the emitter layer.

11. The photovoltaic structure according to claim 9, wherein, in the added layer, gallium is less than aluminum where the added layer is close to the window layer.
